(19) United States
(12) Patent Application Publication
(10) Pub. No.: US 2003/0059968 A1
(43) Pub. Date: Mar. 27, 2003

(54) Method of producing field emission display

(75) Inventors: Huang-Chung Cheng, Hsinchu (TW); Fu-Gow Tarntair, Hsinchu (TW); Kuo-Ji Chen, Hsinchu (TW)

Correspondence Address: BEVER HOFFMAN & HARMS, LLP, 2099 GATEWAY PLACE, SUITE 320, SAN JOSE, CA, 951101017

(73) Assignee: National Science Council

(21) Appl. No.: 10/280,508

(22) Filed: Oct. 25, 2002

Related U.S. Application Data
(62) Division of application No. 09/703,433, filed on Oct. 31, 2000, now abandoned.

(30) Foreign Application Priority Data
Aug. 3, 2000 (TW) 089115620

(51) Int. Cl. H01L 21/00

(52) U.S. Cl. 438/20

(57) ABSTRACT

A method for producing a field emission display, especially for producing a carbon nanotube field emission display, is invented. The invention is to produce a field emission display via different control media, e.g. diode or triode field emission arrays. In addition, the invention discloses the procedure of controlling the field emission array of carbon nanotube stably by thin film transistor technology, and provides the method of producing the collimated carbon nanotube.

### FIELD OF THE INVENTION

This invention discloses a method for producing a field emission display via different control media, e.g. diode or triode field emission arrays, especially for producing a carbon nanotube field emission display. In addition, the invention discloses the procedure of controlling the field emission array of carbon nanotube stably by thin film transistor technology, and provides the method of producing the collimated carbon nanotube.

### BACKGROUND OF THE INVENTION

Currently, the field of vacuum microelectronics is in progressive development due to the full-growth of semiconductor technology. The most important part of vacuum microelectronics is using silicon (Si) as the major element, so the different types of field emission arrays were broadly studied. In order to achieve the application of the field emission array, it is an inevitable trend that the low operating voltage and high efficiency field emission cathodes will be developed. So, the smaller the surface powder function or geometry structure are, the better the field emission cathode is The property of silicon substrate is easy to make different types of emission tips via IC technical processing to reduce the geometry structure However, the application of silicon in field emission devices is limited because of the other properties of silicon including high power function, low conductivity, and low stability

On the other hand, the carbon nanotube has excellent field emission anode capacity, because the size of tube is under nanometer and the cylinder part of tube is full with π-electrons. In addition, the research results indicate that the carbon nanotube is highly potential to be applied in vacuum microelectronics, especially in the process of field emission display, because its field emission current is very high and its threshold voltage is very low

Carbon nanotube has been discovered within the procedure of C₆₀ synthesis in the end of 1980s. The study of the field emission property indicates that the carbon nanotube has a potential to become a high efficiency electrode material for field emission. In addition, recent research reports indicate the possibility of aligned growing of carbon nanotube, so it could be expected that the opportunity of the carbon nanotube applied to the production of field emission display will increase. The major method to grow carbon nanotube is the chemical vapor deposition (CVD). An important property of the carbon nanotube grew by the chemical vapor deposition is selectively growing on catalytic metal layer Therefore, it is a simple way to get the designed field emission array using the light-off process. In addition, the advantage of this process is suitable to produce the large area field emission display.

Presently several literatures indicate that the field emission capacity of carbon nanotube is excellent So, it is not difficult to produce the field emission array with a low operating voltage using the carbon nanotube The stability problem of partial materials could be solved by different thermal treatments and film depositions. However, it is hard to maintain reliable steady field emission current of carbon nanotube The major reason causing unstable condition may result from that the structure of carbon nanotube is not strong enough to sustain the heavy current passing there through, and the factors could be, for example, the alternation of vacuum conditions, or the geometry shape change of carbon nanotube due to the current passing there through etc. Therefore, how to maintain the stability and reliability of carbon nanotube field emission current is a critical issue.

For reducing the processing cost, it is necessary to produce displays using the large area procedure So, presently, the common procedure for producing the field emission display by carbon nanotube is mass-produced by electric arc discharge or hot filament chemical vapor deposition for collecting the carbon nanotube, mixing the carbon nanotube with binder, and sequentially printing the carbon nanotube on the substrate. However, the traditional procedure is hard to make all of carbon nanotubes achieve collimation even using the micro-brush to brush them straightly For overcoming those disadvantages of the traditional procedure, this invention was designed with a method of producing the field emission display as desired.

### SUMMARY OF THE INVENTION

The first goal of this invention is providing a method of producing field emission display by the carbon nanotube. The invention is applying the producing method of carbon nanotube to the field emission display. Using different control media including diode, triode, thin film transistor (TFT), vertical field addition, and negative bias addition, the procedure of large area display will be significantly improved

The second goal of the invention is providing a method of improving the stability of carbon nanotube Using the method of controlling the field emission current of carbon nanotube to control the growth of carbon nanotubes, the traditional procedure of field emission gate will be simplified, the quality of field emission display will be improved, and the producing cost will be reduced.

According to the present invention, a method for producing the field emission display of the carbon nanotube comprises following steps of: providing a substrate; forming a catalytic metal layer on the substrate, and using the chemical vapor deposition to grow the carbon nanotube on the substrate having the catalytic metal layer thereon

Preferably, the catalytic metal layer is made of a material selected from a group consisting of Ni, Co, Fe, Pt, and Pd. The catalytic metal layer is formed on the substrate by one method selected from a group consisting of thermal evaporation, laser peel plating, electron beam evaporation, and sputtering deposition.

The chemical vapor deposition is one selected from a group consisting of microwave plasma chemical vapor deposition, thermochemical vapor deposition, electron cyclotron resonance chemical vapor deposition, and electric arc discharge chemical vapor deposition. The reactive gas of the chemical vapor deposition is one selected from a group consisting of methane (CH₄), hydrogen (H₂), nitrogen (N₂), silicon hydride (SiH₄), boron hydride (B₂H₆), and mixed gases thereof The relevant gas velocities are 3-20 sccm, 100-1000 sccm, 3-8 sccm, and 1-10 sccm. The substrate is heated to a temperature ranged from 200° C. to 1000° C. The microwave plasma chemical vapor deposition is performed at a microwave power ranged from 300 W to 2000 W.

The carbon nanotube is a tube made of a material selected from a group consisting of carbon, carbon and nitrogen composition, boron, carbon and nitrogen composition, boron and nitrogen composition, silicon and carbon composition, and silicon, carbon and nitrogen composition. The carbon nanotube has a radius less than 100 nm and a length ranged from 10 to 500 μm. The carbon nanotube is one of hollow tube and multi-layer hollow tube

According to one aspect of the present invention, a method of manufacturing diode field emission array of carbon nanotube comprises following steps of providing a substrate; forming an array pattern peeling layer on the substrate and exposing a portion of said substrate; forming a catalytic metal layer on the array pattern peeling layer and the exposed portion of substrate; removing the array pattern peeling layer while removing portion of catalytic metal layer on the exposed portion of substrate; and growing the carbon nanotube on the remained portion of catalytic metal layer by using the chemical vapor deposition.

Preferably, the peeling layer is made of a material selected from a group consisting of photoresist, silicon oxide, silicon nitride, and metal. The peeling layer is removed by a solution selected from a group consisting of acetone, buffer oxide etching solution, phosphoric acid solution and acid solution The photoresist is formed by spin coating.

According to a further aspect of the present invention, a method of manufacturing triode field emission array of carbon nanotube comprises following steps of providing a substrate, orderly forming an insulating layer, a gate layer, and a peeling layer on the substrate; removing portion of the peeling layer, the gate layer and the insulating layer to form the array pattern, and exposing portion of the substrate, forming a catalytic metal layer on remained peeling layer and the exposed portion of substrate, removing the remained peeling layer while retaining the portion of the catalytic metal layer on the exposed portion of substrate; and growing the carbon nanotube on the remained portion of catalytic metal layer by using the chemical vapor deposition.

Preferably, the insulating layer is made of a material selected from one of silicon oxide and silicon nitride. The gate layer is made of a material selected from one of polysilicon and metal

The step of forming the array pattern is performed by active ion etching (TEL5000) method. The active reaction gas of the active ion etching method is one selected from a group consisting of CF₄, CHF₃, and Argon

According to another aspect of the present invention, a method of manufacturing a field emission array of carbon nanotube with an active control thin film transistor structure comprises following steps of: forming the thin film transistor structure having an active region, a source, and a drain on a substrate; forming a peeling layer on the thin film transistor structure; removing a portion of peeling layer to expose portion of the drain and forming a catalytic metal layer on the exposed portion of drain; and removing the remained portion of the peeling layer and growing the carbon nanotube on the catalytic metal layer by the chemical vapor deposition.

Preferably, the thin film transistor is one of metal oxide semiconductor field effect transistor (MOS) and bipolar junction transistor (BJT)

The procedure for forming the thin film transistor structure comprises following steps of: providing the substrate, growing one of a polysilicon and amorphous silicon layer on the substrate, forming the active region by a first stage photolithography and etching, growing continuosly a gate dielectric layer and a polysilicon layer; defining a gate by a secondary stage photolithography and etching and exposing the source and drain

The peeling layer is preferably photoresist. The photoresist is removed by acetone The photoresist is formed by spin coating

According to additional aspect of the present invention, a method of producing collimated carbon nanotubes comprises following steps of: providing plural carbon nanotubes; mixing the plural carbon nanotubes with a binder; adhering the plural carbon nanotubes to a substrate; adding a vertical electric field between the plural carbon nanotubes and the substrate; and removing the binder to form the collimated carbon nanotubes.

Preferably, the plural carbon nanotubes are grown by the chemical vapor deposition.

Certainly, the binder can be photoresist. The plural carbon nanotubes mixed with the binder are adhered to the substrate by one of spin coating and printing.

The vertical electric field is preferably a direct current electric field. The voltage of the vertical electric field is ranged from 10V to 500V. The binder is removed by thermal treatment.

According to a further aspect of the present invention, a method of producing the collimated carbon nanotubes comprises following steps of growing plural carbon nanotubes on a substrate by plasma chemical vapor deposition, and simultaneously adding a negative bias on the substrate, thereby forming the collimated carbon nanotube.

Preferably, the plasma chemical vapor deposition is microwave plasma chemical vapor deposition. The reactive gas of the microwave chemical vapor deposition is selected from a group consisting of methane (CH₄), hydrogen (H₂), nitrogen (N₂), silicon hydride (SiH₄), boron hydride (B₂H₆), and mixed gases thereof The microwave plasma chemical vapor deposition is performed at a power ranged from 300 W to 2000 W.

The present invention may best be understand through the following description with reference to the accompanying drawings, in which

### BRIEF DESCRIPTION OF THE DRAWINGS

FIGS. 1A-1E are schematic sectional views illustrating the producing procedure of diode field emission array of carbon nanotube;

FIGS. 2A-2E are schematic sectional views illustrating the producing procedure of triode field emission array of carbon nanotube; and

FIGS. 3A-3H are schematic sectional views illustrating the procedure that the formation of thin film transistor active controls the production of the field emission array of carbon nanotube.

### DETAILED DESCRIPTION OF THE PREFERRED EMBODIMENTS

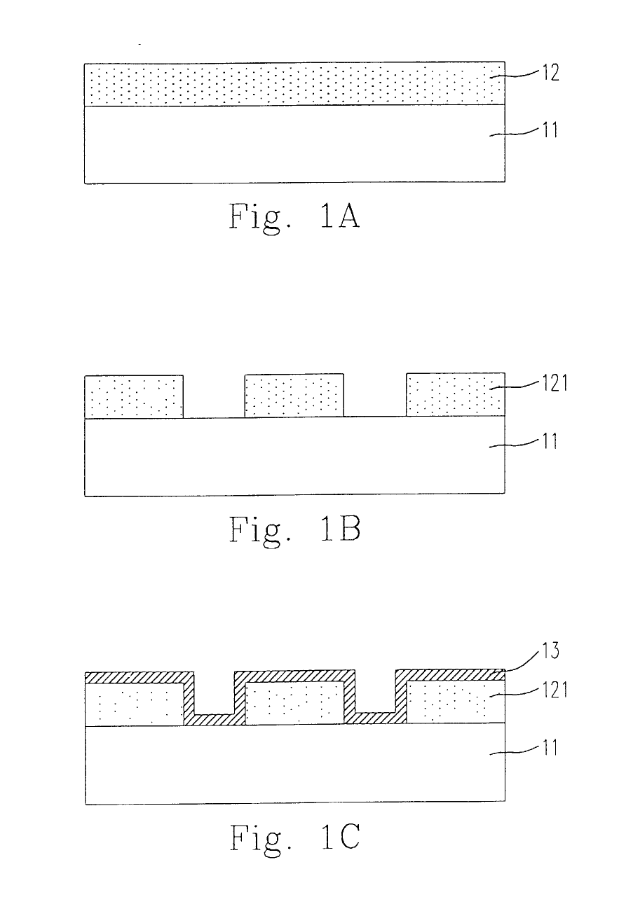

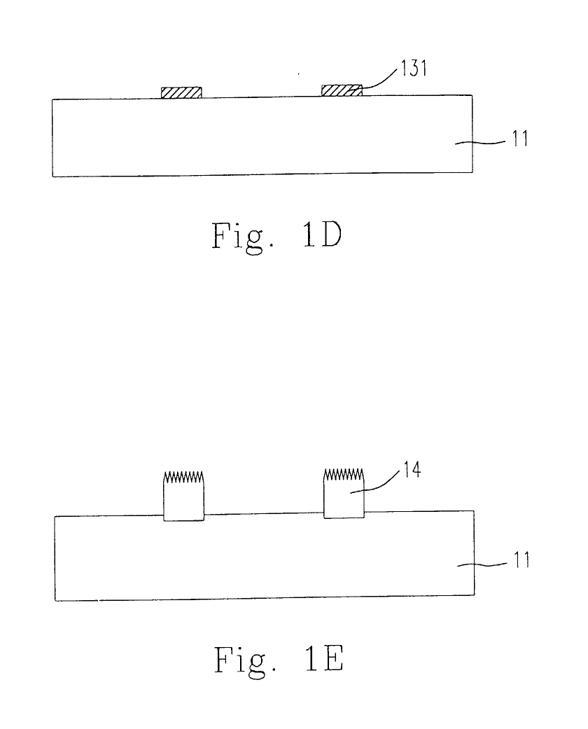

FIG. 1 is a preferred embodiment of the present invention that shows a method for producing diode field emission array of carbon nanotube. As shown in FIG. 1A, first, a peeling layer 12 was formed on a substrate 11 by using photoresist spin coating. Secondly, using photolithography, the peeling layer with array pattern 121 was formed on the substrate and the portion of substrate was exposed (see FIG. 1B). Sequentially, as shown in FIG. 1C, a catalytic metal layer 13 was formed on the pattern peeling layer 121 and the exposed portion of substrate. FIG. 1D shows the removing of the peeling layer to leave the portion of catalytic metal layer 131 on the exposed portion of substrate Finally, as shown in FIG. 1E, the carbon nanotube 14 was grown on the substrate with the portion of catalytic metal layer using chemical vapor deposition.

Preferably, the catalytic metal layer is made of a material selected from a group consisting of Ni, Co, Fe, Pt, and Pd. The catalytic metal layer is formed on the substrate by one method selected from a group consisting of thermal evaporation, laser peel plating, electron beam evaporation, and sputtering deposition. The chemical vapor deposition is one selected from a group consisting of microwave plasma chemical vapor deposition, thermochemical vapor deposition, electron cyclotron resonance chemical vapor deposition, and electric arc discharge chemical vapor deposition. The reactive gas of the chemical vapor deposition is one selected from a group consisting of methane (CH₄), hydrogen (H₂), nitrogen (N₂), silicon hydride (SiH₄), boron hydride (B₂H₆), and mixed gases thereof. The relevant gas velocities are 3-20 sccm, 100-1000 sccm, 3-8 sccm, and 1-10 sccm. The substrate is heated to a temperature ranged from 200° C. to 1000° C. The microwave plasma chemical vapor deposition is performed at a microwave power ranged from 300 W to 2000 W.

The carbon nanotube can be a tube made of a material selected from a group consisting of carbon, carbon and nitrogen composition, boron, carbon and nitrogen composition, boron and nitrogen composition, silicon and carbon composition, and silicon, carbon and nitrogen composition. The carbon nanotube has a radius less than 100 nm and a length ranged from 10 to 500 μm The carbon nanotube is one of hollow tube and multi-layer hollow tube.

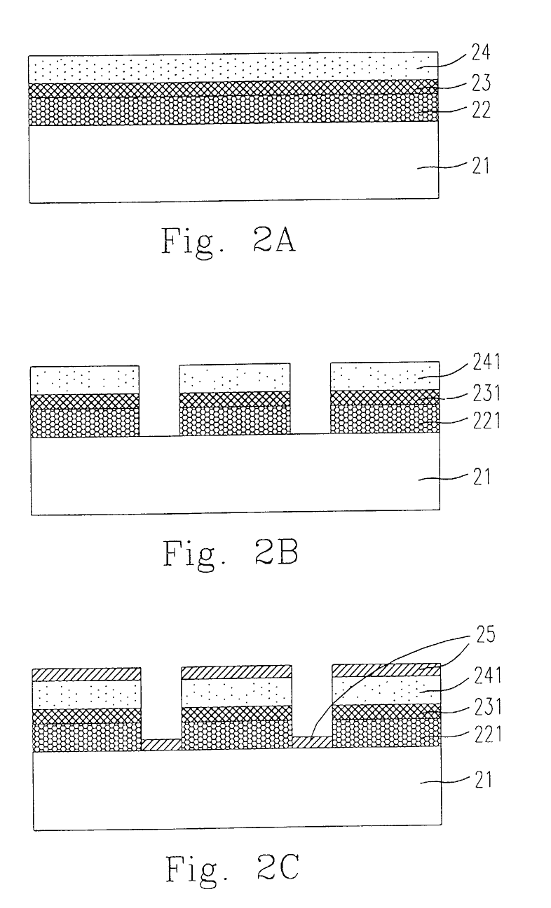

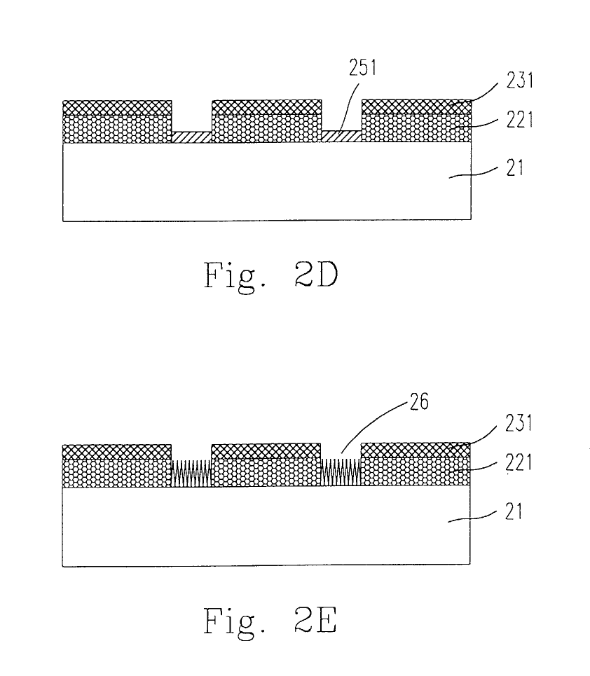

FIG. 2 is another preferred embodiment of the present invention that shows a method of producing triode field emission array of carbon nanotube As the arrangement shown in FIG. 2A, an insulating layer 22, a gate layer 23, and a peeling layer 24 were formed on a substrate 21 orderly After photolithography, the portions of peeling layer, gate layer, and insulating layer were removed to leave the portion of peeling layer with array pattern 241, the portion of gate layer 231, and the portion of insulating layer 221, and to expose the portion of substrate as shown in FIG. 2B. Sequentially, FIG. 2C shows that a catalytic metal layer 25 was formed on the peeling layer with array pattern and the exposed portion of substrate. The peeling layer 241 was removed again to leave the portion of catalytic metal layer 251 on the exposed portion of substrate (see FIG. 2D). Finally, as shown in FIG. 2E, the carbon nanotube 26 was grown on the portion of substrate with catalytic metal layer by the chemical vapor deposition.

In addition, the operating parameters and conditions of the chemical vapor deposition and the procedure are the same as those of the previous embodiment.

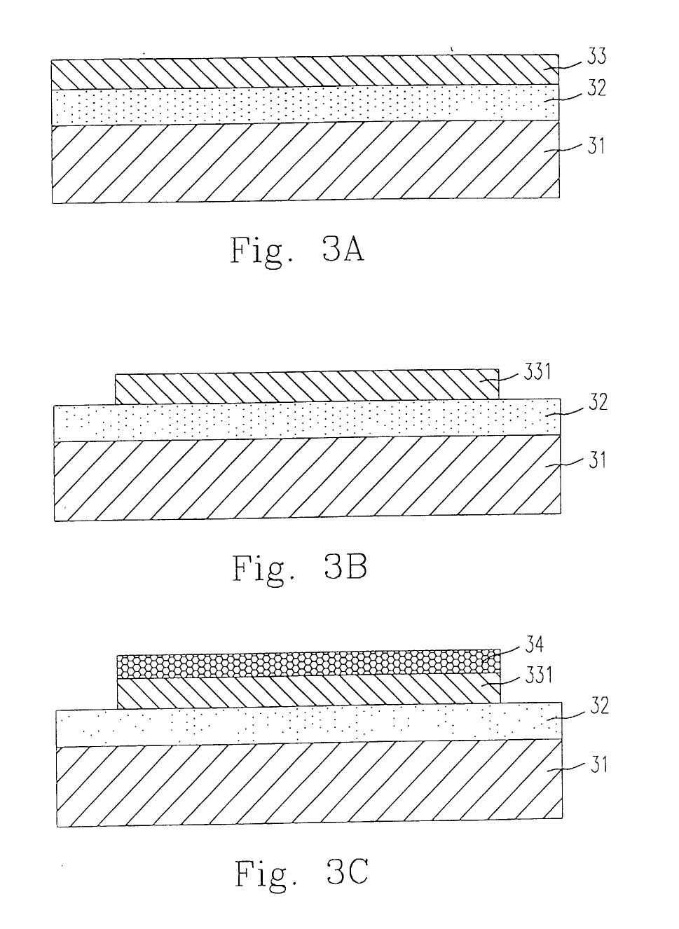

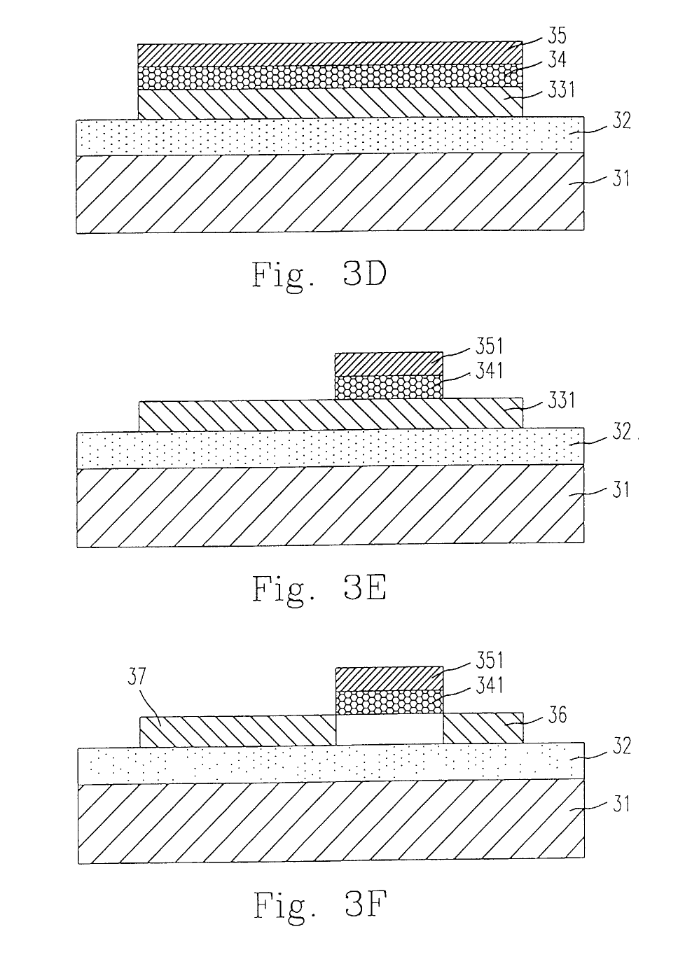

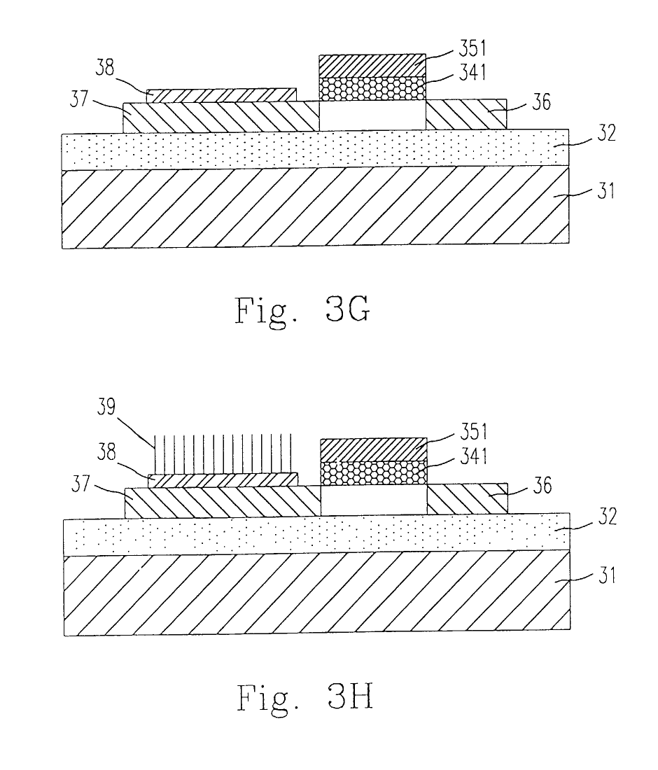

FIG. 3 is the most preferred embodiment of the present invention that shows a method of producing field emission array of carbon nanotube with active control thin film transistor structure. As shown in FIG. 3A, an insulating layer 32 and a polysilicon or amorphous silicon layer 33 were grown on a substrate 31 After first stage photolithography and etching treatment, the active region 331 was formed as shown in FIG. 3B Sequentially, the gate dielectric layer 34 and the polysilicon layer 35 were formed on the active region in order as shown in FIGS. 3C and 3D. After the secondary stage photolithography and etching treatment, the remained portions of polysilicon layer 351 and of gate dielectric layer 341 present after the formation of source junction zone and drain junction zone (see FIG. 3E). Further, the thin film transistor structure was formed with a source 36 and a drain 37 as shown in FIG. 3F Sequentially, a peeling layer was formed on the thin film transistor structure. The portion of peeling layer was removed via a third stage photolithography and etching treatment, to expose the portion of drain and to form a catalytic metal layer 38 (see FIG. 3G). Finally, as shown in FIG. 3H, the carbon nanotube 39 was grown on the portion of substrate with catalytic metal layer by the chemical vapor deposition.

The thin film transistor can be one of metal oxide semiconductor field effect transistor (MOS) and bipolar junction transistor (BJT).

The procedure for forming the thin film transistor structure may comprise following steps of: providing the substrate, growing one of a polysilicon and amorphous silicon layer on the substrate; forming the active region by a first stage photolithography and etching; growing continuously a gate dielectric layer and a polysilicon layer; defining a gate by a secondary stage photolithography and etching and exposing the source and drain.

The peeling layer is photoresist. The photoresist is removed by acetone. The photoresist is formed by spin coating.

In addition, the operating parameters and conditions of chemical vapor deposition and procedure are the same as those of the previous embodiment.

As another preferred embodiment, the present invention provides a method of producing the collimated carbon nanotube The steps include providing plural carbon nanotubes; mixing the plural carbon nanotubes with a binder, adhering the plural carbon nanotubes to a substrate; adding a vertical electric field between the plural carbon nanotubes and substrate; and removing the binder to form the collimated carbon nanotubes.

The plural carbon nanotubes can be grown by the chemical vapor deposition.

The binder can be the photoresist. The plural carbon nanotubes mixed with the binder are adhered to the substrate by one of spin coating and printing.

The carbon nanotubes were affected by the addition of vertical electric field directed toward the substrate perpendicularly to achieve collimated property. The vertical electric field is a direct current electric field. The voltage of the vertical electric field is ranged from 10V to 500V.

In addition, the operating parameters and conditions of the chemical vapor deposition and the procedure are the same as those of the previous embodiment.

On the other hand, a further preferred embodiment of the present invention provides another method of producing the collimated carbon nanotube. The steps include growing plural carbon nanotubes on a substrate by plasma chemical vapor deposition, and simultaneously adding a negative bias on the substrate, thereby forming the collimated carbon nanotube. The addition of negative pressure on the substrate removed the carbon nanotube without collimated property by etching when the carbon nanotube grew. The negative bias attracted the hydrocarbon ion with the positive charge directed toward the substrate vertically to grow the collimated carbon nanotube. The hydrocarbon ions with positive charge were methane (CH₄) and hydrogen (H₂)

Certainly, the plasma chemical vapor deposition can be microwave plasma chemical vapor deposition. The reactive gas of the microwave chemical vapor deposition is selected front a group consisting of methane (CH₄), hydrogen (H₂), nitrogen (N₂), silicon hydride (SiH₄), boron hydride (B₂H₆), and mixed gases thereof The microwave plasma chemical vapor deposition is performed at a power ranged from 300 W to 2000 W.

In addition, the operating parameters and conditions of the chemical vapor deposition and the procedure are the same as those of the previous embodiment.

According to descriptions of drawings and embodiments, we found this invention providing the producing and controlling methods could significantly simplify the procedure of the field emission display, and further improve the technical level in the optoelectronics industry. So, it is no doubt that the invention has progress and creativity. In addition, the improvement of the producing method of carbon nanotube increasing the stability and the collimated property of carbon nanotube has great competitive potential in the process technology.

While the invention has been described in terms of what are presently considered to be the most practical and preferred embodiments, it is to be understood that the invention need not to be limited to the disclosed embodiment. On the contrary, it is intended to cover various modifications and similar arrangements included within the spirit and scope of the appended claims that are to be accorded with the broadest interpretation so as to encompass all such modifications and similar structures.

What is claimed is:

1. A method of producing a field emission display of a carbon nanotube comprising following steps of:
providing a substrate;
forming a catalytic metal layer on said substrate; and
using a chemical vapor deposition to grow said carbon nanotube on said substrate having said catalytic metal layer thereon.

2. The method of claim 1, wherein said catalytic metal layer is made of a material selected from a group consisting of Ni, Co, Fe, Pt, and Pd.

3. The method of claim 1, wherein said catalytic metal layer is formed on said substrate by one method selected from a group consisting of thermal evaporation, laser peel plating, electron beam evaporation, and sputtering deposition.

4. The method of claim 1, wherein said chemical vapor deposition is one selected from a group consisting of microwave plasma chemical vapor deposition, thermochemical vapor deposition, electron cyclotron resonance chemical vapor deposition, and electric arc discharge chemical vapor deposition.

5 The method of claim 4, wherein a reactive gas of said chemical vapor deposition is one selected from a group consisting of methane (CH₄), hydrogen (H₂), nitrogen (N₂), silicon hydride (SiH₄), boron hydride (B₂H₆), and mixed gases thereof

6 The method of claim 1, wherein said substrate is heated to a temperature ranged from 200° C. to 1000° C.

7 The method of claim 4, wherein said microwave plasma chemical vapor deposition is performed at a microwave power ranged from 300 W to 200 W

8 The method of claim 1, wherein said carbon nanotube is a tube made of a material selected from a group consisting of carbon, carbon and nitrogen composition, boron, carbon and nitrogen composition, boron and nitrogen composition, silicon and carbon composition, and silicon, carbon and nitrogen composition.

9. The method of claim 8, wherein said carbon nanotube has a radius less than 100 nm and a length ranged from 10 to 500 μm.

10. The method of claim 8, wherein said carbon nanotube is one of hollow tube and multi-layer hollow tube.

11. A method of manufacturing a diode field emission array of a carbon nanotube comprising following steps of:
providing a substrate;
forming an array pattern peeling layer on said substrate and exposing a portion of said substrate;
forming a catalytic metal layer on said array pattern peeling layer and said exposed portion of said substrate;
removing said array pattern peeling layer while removing a portion of catalytic metal layer on said exposed portion of said substrate; and
growing said carbon nanotube on said remained portion of said catalytic metal layer by using a chemical vapor deposition.

12 The method of claim 11, wherein said peeling layer is made of a material selected from a group consisting of photoresist, silicon oxide, silicon nitride, and metal.

13 The method of claim 12, wherein said peeling layer is removed by a solution selected from a group consisting of acetone, buffer oxide etching solution, phosphoric acid solution and acid solution.

14. The method of claim 12, wherein said photoresist is formed by spin coating.

15. A method of manufacturing a triode field emission array of a carbon nanotube comprising following steps of:
providing a substrate;
orderly forming an insulating layer, a gate layer, and a peeling layer on said substrate;
removing portions of said peeling layer, said gate layer and said insulating layer to form an array pattern, and exposing a portion of said substrate;
forming a catalytic metal layer on remained peeling layer and said exposed portion of substrate;
removing said remained peeling layer while retaining a portion of said catalytic metal layer on said exposed portion of said substrate, and
growing said carbon nanotube on said remained portion of said catalytic metal layer by using a chemical vapor deposition.

16. The method of claim 15, wherein said insulating layer is made of a material selected from one of silicon oxide and silicon nitride.

17. The method of claim 15, wherein said gate layer is made of a material selected from one of polysilicon and metal.

18 The method of claim 15, wherein said step of forming said array pattern is performed by an active ion etching (TEL5000) method

19. The method of claim 18, wherein an active reaction gas of said active ion etching method is one selected from a group of consisting of CF₄, CHF₃, and Argon

20 A method of manufacturing a field emission array of a carbon nanotube with an active control thin film transistor structure, comprising following steps of:
forming said thin film transistor structure having an active region, a source, and a drain on a substrate,
forming a peeling layer on said thin film transistor structure; removing a portion of said peeling layer to expose a portion of said drain and forming a catalytic metal layer on said exposed portion of drain; and
removing the remained portion of said peeling layer and growing said carbon nanotube on said catalytic metal layer by a chemical vapor deposition.

21. The method of claim 20, wherein said thin film transistor is one of metal oxide semiconductor field effect transistor (MOS) and bipolar junction transistor (BJT).

22. The method of claim 20, wherein the forming procedure of said thin film transistor structure comprises following steps of:
providing said substrate;
growing one of a polysilicon and amorphous silicon layer on said substrate,
forming said active region by a first stage photolithography and etching;
growing continuously a gate dielectric layer and a polysilicon layer;
defining a gate by a secondary stage photolithography and etching and exposing said source and drain

23 The method of claim 20, wherein said peeling layer is photoresist.

24. The method of claim 23, wherein said photoresist is removed by acetone

25. The method of claim 23, wherein said photoresist is formed by spin coating.

26. A method of producing collimated carbon nanotubes comprising following steps of:
providing plural carbon nanotubes;
mixing said plural carbon nanotubes with a binder;
adhering said plural carbon nanotubes to a substrate;
adding a vertical electric field between said plural carbon nanotubes and said substrate; and
removing said binder to form said collimated carbon nanotubes.

27. The method of claim 26, wherein said plural carbon nanotubes are grown by a chemical vapor deposition.

28. The method of claim 26, wherein said binder is photoresist.

29. The method of claim 26, wherein said plural carbon nanotubes mixed with said binder are adhered to said substrate by one of spin coating and printing.

30. The method of claim 26, wherein said vertical electric field is a direct current electric field

31. The method of claim 30, wherein the voltage of said vertical electric field is ranged from 10V to 500V.

32. The method of claim 26, wherein said binder is removed by a thermal treatment.

33. A method of producing collimated carbon nanotubes comprising following steps of growing plural carbon nanotubes on a substrate by a plasma chemical vapor deposition, and simultaneously adding a negative bias on said substrate, thereby forming said collimated carbon nanotubes.

34. The method of claim 33, wherein said plasma chemical vapor deposition is a microwave plasma chemical vapor deposition.

35. The method of claim 34, wherein a reactive gas of said microwave chemical vapor deposition is selected from a group consisting of methane (CH₄), hydrogen (H₂), nitrogen (N₂), silicon hydride (SiH₄), boron hydride (B₂H₆), and mixed gases thereof.

36. The method of claim 34, wherein said microwave plasma chemical vapor deposition is performed at a power ranged from 300 W to 2000 W.
